(19) United States
(12) Patent Application Publication
(10) Pub. No.: US 2026/0164578 A1
(43) Pub. Date: Jun. 11, 2026

(54) OPTICAL MEMBER AND OPTICAL DISPLAY DEVICE COMPRISING SAME

(71) Applicant: SAMSUNG SDI CO., LTD., Yongin-si Gyeonggi-do (KR)

(72) Inventors: Kyoung Gon PARK, Suwon-si (KR); Gwang Hwan LEE, Suwon-si (KR); Ji Young HAN, Suwon-si (KR); Do Young KIM, Suwon-si (KR)

(21) Appl. No.: 18/707,520

(22) PCT Filed: Nov. 2, 2022
(86) PCT No.: PCT/KR2022/017046

§ 371 Date: May 3, 2024

(30) Foreign Application Priority Data
Nov. 5, 2021 (KR) 10-2021-0151488

(51) Int. Cl. H05K 5/03; G02B 1/14

(52) U.S. Cl. CPC H05K 5/03; G02B 1/14

(57) ABSTRACT

Provided are an optical member and an optical display device comprising the same, the optical member comprising a substrate layer, and an impact-resistant layer and an adhesive layer sequentially stacked on the bottom surface of the substrate layer, wherein the impact-resistant layer has a groove on the adhesive layer and flat parts at both sides of the groove, and satisfies formula 1.

### TECHNICAL FIELD

The present invention relates to an optical member and an optical display device including the same.

### BACKGROUND ART

Recently, with increasing interest in foldable display devices, various optical elements used in foldable display devices are also required to be foldable. Accordingly, instead of a glass plate, a polyimide film or an ultra-thin glass plate is disposed at the outermost side of a display device to secure foldability of the display device.

However, the polyimide film and the ultra-thin glass plate are vulnerable to external impact or indentation. When a stylus pen is used on the polyimide film or the ultra-thin glass plate, the stylus pen can cause impact or indentation-induced defects, such as bright spots and cracks, on a window and a panel. Accordingly, an optical member is further stacked on an upper surface of the polyimide film or the ultra-thin glass plate, that is, on the outermost side of the display device, to reduce occurrence of bright spots and cracks.

In order to secure foldability of the optical member, there has been proposed a method of forming a groove on the outermost layer among a plurality of layers constituting the optical member. However, since the optical member is disposed at a viewer side of the display device, there is a problem that the groove is easily visible.

Therefore, there is a need for an optical member that has good foldability by securing low repulsive force even upon repeated folding, can minimize or eliminate visibility of a groove, and exhibits good impact or indentation resistance.

The background technique of the present invention is disclosed in Korean Patent Laid-open Publication No. 10-2013-0010233 and the like.

### DISCLOSURE

### Technical Problem

It is one aspect of the present invention to provide an optical member that can be used in a foldable display device by securing good impact or indentation resistance and low repulsive force even upon repeated folding.

It is another aspect of the present invention to provide an optical member that can be disposed at an outermost side of a display device by minimizing or eliminating visibility of a groove.

### Technical Solution

One aspect of the present invention relates to an optical member.

1. The optical member includes: a base layer; and an impact resistance layer and an adhesive layer sequentially formed on a lower surface of the base layer, wherein the impact resistance layer comprises a groove at a side of the adhesive layer and a flat portion at both sides of the groove, and the impact resistance layer satisfies Equation 1.

$$0 \leq H 1 / H 2 < 1 \qquad [ Equation 1 ]$$

(in Equation 1,
H1 is a minimum height from the base layer side to the groove in the impact resistance layer (unit: μm), and
H2 is a height from the base layer side to the flat portion in the impact resistance layer (unit: μm)).

2. In 1, H2 may range from 10 μm to 1,000 μm and H1 may range from 0 m to 200 μm.

3. In 1 to 2, the groove may include a first surface corresponding to an uppermost surface and an inclined surface connecting the first surface to the flat portion.

4. In 3, the inclined surface may include a convex portion extending from the flat portion and a concave portion extending from the convex portion, and each of the convex portion and the concave portion may be a curved surface.

5. In 4, the inclined surface may satisfy Equation 2:

$$L 1 \geq H 3 \qquad [ Equation 2 ]$$

(in Equation 2,
L1 is a width of the inclined surface formed with the convex portion (unit: μm), and
H3 is a height of the inclined surface formed with the convex portion (unit: am)).

6. In 5, L1 may range from greater than 0 μm to 100,000 μm and H3 may range from 1 μm to 300 μm.

7. In 5, the convex portion may have a radius of curvature of 1 mm or more and the concave portion may have a radius of curvature of 1 mm or more.

8. In 1 to 7, the adhesive layer may have a storage modulus of 10 kPa to 500 kPa at 25° C.

9. In 1 to 8, the adhesive layer may have an index of refraction of 1.45 to 1.65.

10. In 1 to 9, the optical member may further include an optical functional layer formed on an upper surface of the base layer.

11. In 10, the optical functional layer may be a hard coating layer.

12. In 11, the hard coating layer may be formed of a urethane (meth)acrylate based hard coating composition comprising a urethane (meth)acrylate based oligomer, a (meth)acrylate based monomer, inorganic particles, and an initiator.

13. In 10, the optical functional layer may include a groove formed on an upper surface thereof opposite the base layer and a flat portion at both sides of the groove.

14. In 13, the groove may include a second surface and an inclined surface connected to the second surface, the inclined surface may be formed with at least one convex portion extending from the flat portion and a concave portion connected to the convex portion, and the inclined surface may satisfy Equation 4.

$$a \geq b \qquad [ Equation 4 ]$$

(in Equation 4,
a is a width of the inclined surface formed with the convex portion (unit: μm), and
b is a height of the inclined surface formed with the convex portion (unit: μm)).

Another aspect of the present invention relates to an optical display device including the optical member according to the present invention.

### Advantageous Effects

The present invention provides an optical member that can be used in a foldable display device by securing good impact or indentation resistance and low repulsive force even upon repeated folding.

The present invention provides an optical member that can be disposed at an outermost side of a display device by minimizing or eliminating visibility of a groove.

### DESCRIPTION OF DRAWINGS

FIG. 1 is a sectional view of an optical member according to one embodiment of the present invention.

FIG. 2 is a partially enlarged cross-sectional view of an impact resistance layer of the optical member shown in FIG. 1.

FIG. 3 is a conceptual view illustrating radii of curvature set forth herein.

FIG. 4 is a perspective view of the optical member according to the embodiment of the present invention.

FIG. 5 is a partially enlarged cross-sectional view of a hard coating layer of an optical member according to another embodiment of the present invention.

### BEST MODE

Hereinafter, exemplary embodiments of the present invention will be described in detail with reference to the accompanying drawings to facilitate practice by one of ordinary skill in the art to which the present invention pertains. It should be understood that the present invention may be embodied in different ways and is not limited to the following embodiments.

In the drawings, portions irrelevant to the description will be omitted for clarity. Like components will be denoted by like reference numerals throughout the specification. Lengths, sizes, and the like of components in the drawings are for the purpose of illustrating the invention, and the invention is not limited thereto.

Herein, spatially relative terms such as “upper” and “lower” are defined with reference to the accompanying drawings. Thus, it will be understood that the term “upper surface” can be used interchangeably with the term “lower surface”.

Herein, “Young's modulus” of a base layer is measured on a type V specimen at a temperature of 25° C. and at a tensile rate of 100 mm/min using a universal testing machine (UTM) (Instron Corp.) in accordance with ASTM D638.

Herein, “storage modulus” of a base layer is measured at −20° C. and 85° C. in tensile test mode under conditions of a frequency of 1 Hz and a heating rate of 2° C./min from −70° C. to 120° C. using a dynamic mechanical analyzer (DMA) and means values measured at −20° C. to at 80° C.

Herein, “storage modulus” of an adhesive layer is a value measured in auto-strain mode with a strain of 1% while increasing a shear rate from 0.1 rad/sec to 100 rad/sec using a dynamic viscoelastic rheometer (ARES G2, TA Instruments). The storage modulus is measured while increasing temperature from −20° C. to 90° C. at a rate of 5° C./min. A specimen for evaluation of storage modulus is prepared by stacking 50 μm thick adhesive layers to a thickness of 500 μm, followed by punching the resulting stack using a punching machine having a diameter of 8 mm.

Herein, the term “(meth)acryl” refers to acryl and/or methacryl.

Herein, “average particle diameter” of organic particles refers to a Z-average particle diameter measured in an aqueous or organic solvent using a Zetasizer nano-ZS (Malver Inc.) and confirmed through SEM/TEM observation.

As used herein to represent a specific numerical range, “X to Y” means “X<and <Y”.

The present invention provides an optical member that can be used in a foldable display device by securing good impact or indentation resistance and low repulsive force even upon repeated folding. The present invention provides an optical member that can be disposed at the outermost side of a display device by minimizing or eliminating visibility of a groove

In one embodiment, the optical member may be disposed at a viewer side of an optical display device. Specifically, the optical member may be disposed at a viewer side of the optical display device with an optical functional layer disposed as the outermost layer of the optical member.

The optical member includes: a base layer; and an impact resistance layer and an adhesive layer sequentially formed on a lower surface of the base layer, wherein the impact resistance layer includes a groove at a side of the adhesive layer and a flat portion at both sides of the groove, and satisfies Equation 1.

$$0 \leq H 1 / H 2 < 1 \qquad [ Equation 1 ]$$

(in Equation 1,
H1 is a minimum height from the base layer side to the groove in the impact resistance layer (unit: μm), and
H2 is a height from the base layer side to the flat portion in the impact resistance layer (unit: μm)).

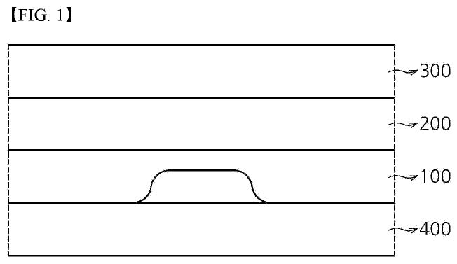

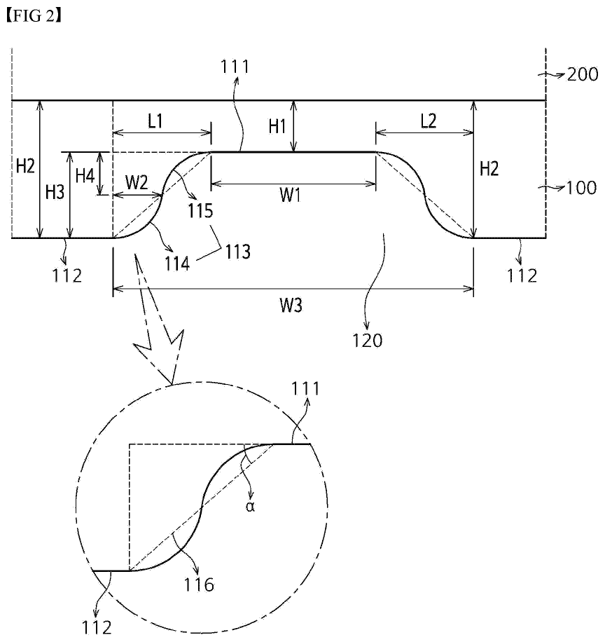

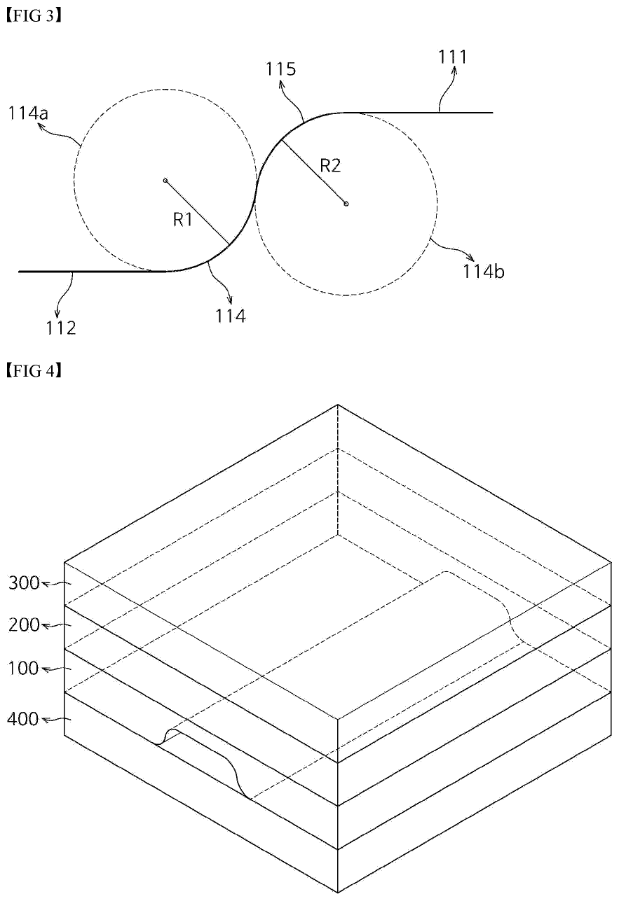

Hereinafter, an optical member according to one embodiment of the present invention will be described with reference to FIG. 1, FIG. 2, FIG. 3, and FIG. 4.

The optical member may include a base layer (200); an impact resistance layer (100) and an adhesive layer (400) sequentially formed on a lower surface of the base layer (200); and an optical functional layer (300) formed on an upper surface of the base layer (200).

### [Base Layer]

The base layer (200) may support the optical member. In one embodiment, each of upper and lower surfaces of the base layer (200) may be a generally flat surface.

The base layer (200) may include a film or coating layer formed of a composition including an optically clear resin. For example, the base layer may be formed of at least one resin selected from among cellulose based resins including triacetyl cellulose (TAC), polyester based resins including polyethylene terephthalate (PET), polybutylene terephthalate, polyethylene naphthalate, and polybutylene naphthalate, cyclic polyolefin based resins, polycarbonate based resins, polyether sulfone based resins, polysulfone based resins, polyamide based resins, polyimide based resins, polyolefin based resins, polyarylate based resins, polyvinyl alcohol based resins, polyvinyl chloride based resins, polyvinylidene chloride r based esins, and polyurethane based resins.

In one embodiment, the base layer may be a polyester based film including polyethylene terephthalate (PET), polybutylene terephthalate, polyethylene naphthalate, polybutylene naphthalate, and the like, or a polyimide based film, preferably a PET film. The PET film may provide light-transmissive properties to the optical member.

In another embodiment, the base layer may be a polyurethane based resin film. The polyurethane based resin film may help to improve impact resistance, indentation resistance, and flexural reliability at low and high temperatures of the optical member.

The polyurethane based resin may be prepared from a bi- or higher functional polyol and a bi- or higher functional isocyanate. The bi- or higher functional polyol may include at least one selected from among an aromatic polyol, an aliphatic polyol, and an alicyclic polyol. The bi- or higher functional isocyanate may include any aliphatic, alicyclic or aromatic isocyanate. The polyurethane based resin may be prepared by any typical method known to those skilled in the art.

The polyurethane based resin film may include a thermoplastic polyurethane based resin film prepared by melt extrusion using the polyurethane based resin or a cast polyurethane based resin film prepared by solution casting. As compared with the thermoplastic polyurethane based resin film, the cast polyurethane based resin film is completely free from striping, gelling, and/or opacity when irradiated with light and is thus advantageous for improving appearance of the optical member.

The base layer, preferably the polyurethane based resin film, may have a Young's modulus of 80 MPa to 500 MPa, for example, 80, 90, 100, 110, 120, 130, 140, 150, 160, 170, 180, 190, 200, 210, 220, 230, 240, 250, 260, 270, 280, 290, 300, 310, 320, 330, 340, 350, 360, 370, 380, 390, 400, 410, 420, 430, 440, 450, 460, 470, 480, 490, or 500 MPa, preferably 80 MPa to 300 MPa, more preferably 100 MPa to 200 MPa, as measured at 25° C. Within this range, the base layer can help to improve impact resistance and flexural reliability at low and high temperatures of the optical member.

The base layer, preferably the polyurethane based resin film, may have a storage modulus of 900 MPa to 1,500 MPa, for example, 900, 950, 1,000, 1,050, 1,100, 1,150, 1,200, 1,250, 1,300, 1,350, 1,400, 1,450, or 1,500 MPa, specifically 900 MPa to 1,200 MPa, as measured at −20° C. Within this range, a manufacturing process of the polyurethane resin film can be facilitated and the optical member can have good folding reliability at low temperature.

The base layer, for example, the polyurethane based resin film, may have a storage modulus of 15 MPa to 100 MPa, for example, 15, 20, 25, 30, 35, 40, 45, 50, 55, 60, 65, 70, 75, 80, 85, 90, 95, or 100 MPa, specifically 50 MPa to 90 MPa, as measured at 85° C. Within this range, the manufacturing process of the polyurethane resin film can be facilitated and the optical member can have good flexural reliability under high temperature conditions and/or high temperature and high humidity conditions.

The Young's modulus and storage modulus of the base layer may be adjusted to the above ranges by adjusting a ratio between monomers constituting a resin forming the base layer or by adjusting a molecular weight of the resin.

The base layer (200) may have a thickness of 10 μm to 200 μm, for example, 10, 20, 30, 40, 50, 60, 70, 80, 90, 100, 110, 120, 130, 140, 150, 160, 170, 180, 190, or 200 μm, specifically 50 μm to 100 μm. Within this range, the base layer can help to improve impact resistance and flexural reliability of the optical member while allowing reduction in thickness of the optical member.

### [Impact Resistance Layer]

The impact resistance layer (100) is disposed between the base layer (200) and the adhesive layer (400).

The impact resistance layer (100) provides an optical member that can be used in a foldable display device by securing low repulsive force even upon repeated folding, can minimize or eliminate visibility of a groove described below, and has good impact and indentation resistance.

The impact resistance layer (100) may have an index of refraction of 1.40 to 1.75, for example, 1.40, 1.45, 1.50, 1.55, 1.60, 1.65, 1.70, or 1.75, specifically 1.45 to 1.65. Within this range, the impact resistance layer 100 can help to minimize visibility of a groove described below.

The impact resistance layer (100) may be formed of a composition including a material capable of providing the above index of refraction. In one embodiment, the impact resistance layer (100) may be formed of a composition including a resin, such as a polyurethane based resin, a polyurethane (meth)acrylate based resin, a polycarbonate based resin, a polyimide based resin, a polyester based resin, and the like. The polyurethane, polyurethane (meth)acrylate, polycarbonate, polyimide, polyester based resins, and the like may include typical materials known to those skilled in the art. The impact resistance layer may further include at least one selected from among organic particles, inorganic particles, and organic-inorganic particles to enhance impact resistance effects.

The impact resistance layer (100) includes a groove (120) at a side of the adhesive layer (400); and a flat portion (112) at both sides of the groove (120), and satisfies Equation 1. As a result, the optical member can increase impact resistance while reducing folding repulsive force upon folding.

$$0 \leq H 1 / H 2 < 1 \qquad [ Equation 1 ]$$

(in Equation 1,
H1 is a minimum height from the base layer side to the groove in the impact resistance layer (unit: μm), and
H2 is a height from the base layer side to the flat portion in the impact resistance layer (unit: μm)).

In one embodiment, H1/H2 may range from 0 to 1, for example, greater than 0, 0.01, 0.02, 0.03, 0.04, 0.05, 0.06, 0.07, 0.08, 0.09, 0.1, 0.15, 0.2, 0.25, 0.3, 0.35, 0.4, 0.45, 0.5, 0.55, 0.6, 0.65, 0.7, 0.75, 0.8, 0.85, 0.9, 0.95, or 1, preferably 0.01 to 0.5, more preferably 0.01 to 0.3. Within this range, the optical member can be used in a foldable display device by securing low repulsive force even upon repeated folding.

The groove (120) is formed at a side of the adhesive layer (400) and has an engraved pattern, as compared to the flat portion (112). With this structure, the impact resistance layer (120) provides impact resistance while reducing folding repulsive force upon folding of the optical member, thereby enabling the optical member to be used in a foldable display device. Here, “engraved pattern” refers to a shape protruding from the flat portion of the impact resistance layer toward the base layer.

In one embodiment, the impact resistance layer (100) may include a groove (120), a flat portion (112) extending from one end of the groove (120), and a flat portion (112) extending from the other end of the groove (120).

The flat portion (112) is connected to the groove (120) and may form the lowermost surface of the impact resistance layer. The flat portion (112) may have a greater height from the base layer side than the groove (120), preferably the first surface (111), thereby ensuring that the optical member has high resistance to impact and indentation.

The height (H2) of the impact resistance layer (100) from the base layer (200) side to the flat portion (112) may range from 10 μm to 1,000 μm, for example, 10, 20, 30, 40, 50, 60, 70, 80, 90, 100, 110, 120, 130, 140, 150, 160, 170, 180, 190, 200, 210, 220, 230, 240, 250, 260, 270, 280, 290, 300, 310, 320, 330, 340, 350, 360, 370, 380, 390, 400, 410, 420, 430, 440, 450, 460, 470, 480, 490, 500, 510, 520, 530, 540, 550, 560, 570, 580, 590, 600, 610, 620, 630, 640, 650, 660, 670, 680, 690, 700, 710, 720, 730, 740, 750, 760, 770, 780, 790, 800, 810, 820, 830, 840, 850, 860, 870, 880, 890, 900, 910, 920, 930, 940, 950, 960, 970, 980, 990, or 1,000 μm, specifically μm to 500 μm, specifically 30 μm to 200 μm. Within this range, the indentation layer can improve resistance of the optical member to impact and indentation.

The groove (120) includes an inclined surface (113) and a first surface (111) connected to the inclined surface (113). The groove (120) extends from the flat portion (112) of the impact resistance layer (100) and is formed in an engraved pattern. The groove (120) may reduce folding repulsive force upon folding of the optical member toward the adhesive layer (400) or toward the optical functional layer (300) about a folding axis, as shown in FIG. 4.

The first surface (111) can assist in reduction of the folding repulsive force of the optical member. The first surface (111) can assist in reduction of the folding repulsive force upon folding of the optical member toward the adhesive layer (400) or the optical functional layer (300) about the folding axis, as shown in FIG. 4.

The first surface (111) may form the uppermost surface of the groove (120). The first surface (111) may be a flat surface or a non-flat surface. The non-flat surface is a curved surface and may be a convex surface or a concave surface. Preferably, the first surface (111) is a flat surface to facilitate manufacture of the impact resistance layer (100).

The minimum height (H1) of the impact resistance layer (100) from the base layer (200) side to the groove (120) may range from 0 μm to 200 μm, for example, 0 μm, greater than 0 μm, 5, 10, 15, 20, 25, 30, 35, 40, 45, 50, 55, 60, 65, 70, 75, 80, 85, 90, 95, 100, 105, 110, 115, 120, 125, 130, 135, 140, 145, 150, 155, 160, 165, 170, 175, 180, 185, 190, 195, or 200 μm, for example, greater than 0 μm to 200 m, preferably 1 μm to 50 μm, more preferably 5 μm to 30 μm. Within this range, the impact resistance layer 100 can improve folding properties of the optical member by reducing repulsive force.

The first surface (111) has a maximum width (W1) of greater than 0 m to 50,000 μm, for example, greater than 0 μm, 100, 200, 300, 400, 500, 600, 700, 800, 900, 1,000, 2,000, 3,000, 4,000, 5,000, 6,000, 7,000, 8,000, 9,000, 10,000, 11,000, 12,000, 13,000, 14,000, 15,000, 16,000, 17,000, 18,000, 19,000, 20,000, 21,000, 22,000, 23,000, 24,000, 25,000, 26,000, 27,000, 28,000, 29,000, 30,000, 31,000, 32,000, 33,000, 34,000, 35,000, 36,000, 37,000, 38,000, 39,000, 40,000, 41,000, 42,000, 43,000, 44,000, 45,000, 46,000, 47,000, 48,000, 49,000, or 50,000 μm, for example, 1 μm to 30,000 μm, for example, 5,000 μm to 20,000 μm. Within this range, the impact resistance layer (100) can improve resistance of the optical member to impact and indentation.

The groove (120) includes the inclined surface (113) that connects the first surface (111) to the flat portion (112). The inclined surface (113) may include a curved surface.

The inclined surface (113) is formed with at least a convex portion (114) extending from the flat portion (112). The convex portion (114) is convexly formed from the impact resistance layer (100) side toward the groove (120). The flat portion (112) and the convex portion (114) are directly connected to each other.

The inclined surface (113) may further include a concave portion (115) extending from the convex portion (114). The concave portion (115) is convexly formed from the groove (120) side towards the impact resistance layer (100). The concave portion (115) is connected to the first surface (111).

Each of the convex portion (114) and the concave portion (115) is a curved surface and the inclined surface (113) may satisfy Equation 2:

$$L 1 \geq H 3 \qquad [ Equation 2 ]$$

(in Equation 2,
L1 is the width of the inclined surface formed with the convex portion (unit: μm), and
H3 is the height of the inclined surface formed with the convex portion (unit: μm)).

By satisfying Equation 2, the groove formed for folding repulsive force can minimize or eliminate visibility of the groove, whereby the optical member can be applied to the outermost periphery of a display device.

In one embodiment, L1/H3 may range from 1 to 100,000, for example, 1, 5, 10, 15, 20, 25, 30, 35, 40, 45, 50, 55, 60, 65, 70, 75, 80, 85, 90, 95, 100, 105, 110, 115, 120, 125, 130, 135, 140, 145, 150, 155, 160, 165, 170, 175, 180, 185, 190, 195, 200, 205, 210, 215, 220, 225, 230, 235, 240, 245, 250, 255, 260, 265, 270, 275, 280, 285, 290, 295, 300, 305, 310, 315, 320, 325, 330, 335, 340, 345, 350, 355, 360, 365, 370, 375, 380, 385, 390, 395, 400, 405, 410, 415, 420, 425, 430, 435, 440, 445, 450, 455, 460, 465, 470, 475, 480, 485, 490, 495, 500, 505, 510, 515, 520, 525, 530, 535, 540, 545, 550, 555, 560, 565, 570, 575, 580, 585, 590, 595, 600, 650, 700, 750, 800, 850, 900, 950, 1,000, 1,500, 2,000, 2,500, 3,000, 3,500, 4,000, 4,500, 5,000, 5,500, 6,000, 6,500, 7,000, 7,500, 8,000, 8,500, 9,000, 9,500, 10,000, 20,000, 30,000, 40,000, 50,000, 60,000, 70,000, 80,000, 90,000, or 100,000, preferably 1 to 7000, more preferably 10 to 1,000.

Each of L1 and H3 may be adjusted within the range satisfying Equation 1.

In one embodiment, L1 may range from greater than 0 μm to 100,000 μm, for example, 1, 100, 500, 1,000, 1,500, 2,000, 2,500, 3,000, 35,000, 4,000, 4,500, 5,000, 5,500, 6,000, 6,500, 7,000, 7,500, 8,000, 8,500, 9,000, 9,500, 10,000, 10,500, 11,000, 11,500, 12,000, 12,500, 13,000, 13,500, 14,000, 14,500, 15,000, 15,500, 16,000, 16,500, 17,000, 17,500, 18,000, 18,500, 19,000, 19,500, 20,000, 21,000, 22,000, 23,000, 24,000, 25,000, 26,000, 27,000, 28,000, 29,000, 30,000, 31,000, 32,000, 33,000, 34,000, 35,000, 36,000, 37,000, 38,000, 39,000, 40,000, 41,000, 42,000, 43,000, 44,000, 45,000, 46,000, 47,000, 48,000, 49,000, 50,000, 51,000, 52,000, 53,000, 54,000, 55,000, 56,000, 57,000, 58,000, 59,000, 60,000, 70,000, 80,000, 90,000, or 100,000 μm, specifically 10 μm to 70,000 μm, more specifically 1,000 μm to 20,000 μm, and H3 may range from 1 μm to 300 μm, for example, 1, 5, 10, 15, 20, 25, 30, 35, 40, 45, 50, 55, 60, 65, 70, 75, 80, 85, 90, 95, 100, 105, 110, 115, 120, 125, 130, 135, 140, 145, 150, 155, 160, 165, 170, 175, 180, 185, 190, 195, 200, 205, 210, 215, 220, 225, 230, 235, 240, 245, 250, 255, 260, 265, 270, 275, 280, 285, 290, 295, or 300 μm, specifically 10 μm to 200 μm. Within this range, the effects of the present invention can be easily realized and manufacture of the impact resistance layer can be facilitated.

The convex portion (114) may have a radius of curvature (R1) of 1 mm or more. Within this range, the optical member can exhibit low repulsive force even upon repeated folding to be used in a foldable display device and can improve the effect of minimizing visibility of the groove. If the convex portion (114) has a radius of curvature (R1) of less than 1 mm, the groove can be observed with the naked eye. For example, the convex portion (114) may have a radius of curvature of 1, 5, 10, 15, 20, 25, 30, 35, 40, 45, 50, 55, 60, 65, 70, 75, 80, 85, 90, 95, 100, 105, 110, 115, 120, 125, 130, 135, 140, 145, 150, 155, 160, 165, 170, 175, 180, 185, 190, 195, or 200 mm, preferably 10 mm or more, more preferably 50 mm to 200 mm. Within this range, the impact resistance layer can easily realize the effects of the present invention and can easily improve indentation resistance of the optical member.

The concave portion (115) may have a radius of curvature (R2) of 1 mm or more. Within this range, the optical member can exhibit low repulsive force even upon repeated folding to be applied to a foldable display device and can improve the effect of minimizing visibility of the groove. If the concave portion (115) has a radius of curvature (R2) of less than 1 mm, the groove can be observed with the naked eye. For example, the concave portion (115) may have a radius of curvature of 1, 5, 10, 15, 20, 25, 30, 35, 40, 45, 50, 55, 60, 65, 70, 75, 80, 85, 90, 95, 100, 105, 110, 115, 120, 125, 130, 135, 140, 145, 150, 155, 160, 165, 170, 175, 180, 185, 190, 195, or 200 mm, preferably 10 mm or more, more preferably 50 mm to 200 mm. Within this range, the impact resistance layer can easily realize the effects of the present invention and can easily improve indentation resistance of the optical member.

Referring to FIG. 3, the radii of curvature (R1, R2) mean a radius of an imaginary circle (114a) including the curved surface of the convex portion (114) as part of a circle and a radius of an imaginary circle (115a) including the curved surface of the concave portion (115) as part of the circle, respectively. The inventors of the present invention have studied a solution to reduce repulsive force upon folding of the optical member and to reduce visibility of the groove when the optical member is disposed at a viewer side of a display device. As a result, the inventors of the present invention have confirmed that the aforementioned effects can be achieved by designing each of the convex portion and the concave portion as a curved surface having a radius of curvature of 1 mm or more rather than simply designing the convex portion and the concave portion as curved surfaces.

The height (H4) of the concave portion (113) may be adjusted depending on the degree of folding upon folding of the optical member. For example, the concave portion (113) may have a height (H4) of 1 μm to 300 μm, for example, 1, 5, 10, 20, 30, 40, 50, 60, 70, 80, 90, 100, 110, 120, 130, 140, 150, 160, 170, 180, 190, 200, 210, 220, 230, 240, 250, 260, 270, 280, 290, or 300 μm, specifically 10 m to 200 μm. Within this range, the first convex portion can be easily realized.

The maximum width (W2) of the convex portion (114) may be adjusted depending on the degree of folding upon folding of the optical member. For example, the convex portion (114) may have a maximum width (W2) of 1 μm to 100,000 μm, for example, 1, 100, 500, 1,000, 1,500, 2,000, 2,500, 3,000, 35,00, 4,000, 4,500, 5,000, 5,500, 6,000, 6,500, 7,000, 7,500, 8,000, 8,500, 9,000, 9,500, 1,0,000, 10,500, 11,000, 11,500, 12,000, 12,500, 13,000, 13,500, 14,000, 14,500, 15,000, 15,500, 16,000, 16,500, 17,000, 17,500, 18,000, 18,500, 19,000, 19,500, 20,000, 21,000, 22,000, 23,000, 24,000, 25,000, 26,000, 27,000, 28,000, 29,000, 30,000, 31,000, 32,000, 33,000, 34,000, 35,000, 36,000, 37,000, 38,000, 39,000, 40,000, 41,000, 42,000, 43,000, 44,000, 45,000, 46,000, 47,000, 48,000, 49,000, 50,000, 51,000, 52,000, 53,000, 54,000, 55,000, 56,000, 57,000, 58,000, 59,000, 60,000, 70,000, 80,000, 90,000, 100,000 μm, specifically 1 μm to 70,000 μm. Within this range, the convex portion can be easily realized.

An angle (α) of a plane connecting the flat surface (112) to the first surface (111) with respect to a base of the inclined surface (113) may range from greater than 0° to 45°. Within this range, the inclined surface (113) can easily satisfy Equation 1. Specifically, the angle α may be greater than 0°, 1°, 2°, 3°, 4°, 5°, 6°, 7° 8°, 9° 10°, 11°, 12°, 13°, 14°, 15°, 16°, 17°, 18°, 19°, 20°, 21°, 22°, 23°, 24°, 25°, 26°, 27°,28°, 29°, 30°, 31°, 32°, 33° 34°, 35°, 36°, 37°,38°, 39°,40°, 41°,42°, 43° 44°, or 45°, for example, greater than 0° to 10°.

The groove (120) may be disposed in a folding region when the optical member is used in an optical display device. Thus, depending on the number of folding regions, the optical functional layer may be formed with one or more grooves (120).

A ratio (W1/W3) of the width (W1) of the first surface (111) to the maximum width (W3) of the groove (120) may range from greater than 0 to 0.5, for example, greater than 0, 0.1, 0.15, 0.2, 0.25, 0.3, 0.35, 0.4, 0.45, or 0.5, specifically 0.2 to 0.5. Within this range, the groove can help to secure foldability of the optical member.

The groove (120) may have a maximum width (W3) of 2 μm to 200,000 m, for example, 1, 100, 500, 1,000, 1,500, 2,000, 2,500, 3,000, 35,000, 4,000, 4,500, 5,000, 5,500, 6,000, 6,500, 7,000, 7,500, 8,000, 8,500, 9,000, 9,500, 10,000, 10,500, 11,000, 11,500, 12,000, 12,500, 13,000, 13,500, 14,000, 14,500, 15,000, 15,500, 16,000, 16,500, 17,000, 17,500, 18,000, 18,500, 19,000, 19,500, 20,000, 21,000, 22,000, 23,000, 24,000, 25,000, 26,000, 27,000, 28,000, 29,000, 30,000, 31,000, 32,000, 33,000, 34,000, 35,000, 36,000, 37,000, 38,000, 39,000, 40,000, 41,000, 42,000, 43,000, 44,000, 45,000, 46,000, 47,000, 48,000, 49,000, 50,000, 51,000, 52,000, 53,000, 54,000, 55,000, 56,000, 57,000, 58,000, 59,000, 60,000, 70,000, 80,000, 90,000, 100,000, 110,000, 120,000, 130,000, 140,000, 150,000, 160,000, 170,000, 180,000, 190,000, or 200,000 μm, specifically 50 μm to 100,000 m, 5000 μm to 20,000 m Within this range, the groove can help to secure foldability of the optical member.

The groove (120) may be an empty space, as shown in FIG. 1 and FIG. 2. Alternatively, the groove (120) may be filled with an adhesive or a resin having a predetermined index of refraction. For example, the groove (120) may be filled with an adhesive layer composition described below.

The groove (120) may be symmetric or asymmetric with respect to a centerline of the first surface (111). Whether the groove (120) is symmetric or asymmetric with respect to the centerline of the first surface (111) may depend on the location and width of a folding region when the optical member is used in an optical display device.

Referring to FIG. 4, the groove (120) may have a stripe shape. Herein, “stripe shape” means that the groove (120) extends in a longitudinal direction thereof. The folding axis is formed substantially in the same direction as the longitudinal direction of the groove and the optical member can reduce the folding repulsive force when folded toward the adhesive layer (400) or toward the optical functional layer (300) about the folding axis.

The base layer side of the impact resistance layer (100) may be a generally flat surface.

The impact resistance layer (100) may be formed by coating a composition for the impact resistance layer to a predetermined thickness on a lower surface of the base layer (200), applying an embossed pattern capable of forming a groove, and curing the composition. Alternatively, the impact resistance layer (100) may be formed by coating a composition for the impact resistance layer to a predetermined thickness on an upper surface of the base layer (200), curing the composition, and carving a cured product with a laser beam or the like to form a groove.

### [Adhesive Layer]

The adhesive layer (400) is formed on the lower surface of the impact resistance layer (100) to adhesively attach the optical member to an adherend of a display device.

Herein, “adherend” refers to an optical element incorporated in an optical display device, and may include, for example, a window film, a base film for a window film, and a cover glass, without being limited thereto. In one embodiment, the adherend may be a plastic film including a polyester based film, a polycarbonate based film, a polyimide based film, and the like, or a glass plates including an ultra-thin glass (UTG) plate and the like.

The adhesive layer (400) may have a thickness of 5 μm to 200 μm, specifically 10 μm to 100 μm. Within this range, the adhesive layer (400) can be applied to the optical member and can adhesively attach the base layer to the optical element in a reliable manner.

The adhesive layer (400) may include any typical adhesive layer known to those skilled in the art, for example, a (meth)acrylate based adhesive layer, a urethane based adhesive layer, a urethane (meth)acrylate based adhesive layer, a silicone based adhesive layer, and an epoxy adhesive layer. The adhesive layer may be formed by curing an adhesive layer composition by photocuring, thermal curing, or a combination thereof. Photocuring and/or thermal curing of the composition may be performed by any typical method known those skilled in the art. The adhesive layer 400 has good properties in terms of impact resistance and/or folding reliability, thereby improving effectiveness of the optical member according to the present invention.

The adhesive layer (400) may have a storage modulus of 10 kPa to 500 kPa, specifically 10 kPa to 300 kPa, 10 kPa to 200 kPa, or 10 kPa to 150 kPa, as measured at 25° C. Within this range, the adhesive layer (400) can improve flexural reliability of the optical member while maintaining adhesive strength to the impact resistance layer.

The adhesive layer (400) may have an index of refraction of 1.45 to 1.65, specifically 1.45 to 1.55. Within this range, the adhesive layer can have an appropriate index of refraction relative to the impact resistance layer, thereby helping to ensure good appearance of the optical member.

In one embodiment, the adhesive layer may include a (meth)acrylic adhesive layer formed of an adhesive layer composition including: a monomer mixture for a (meth)acrylic copolymer; and an initiator.

The monomer mixture may include at least one selected from among a hydroxyl group-containing (meth)acrylate, an alkyl group-containing (meth)acrylate, an ethylene oxide-containing monomer, a propylene oxide-containing monomer, an amine group-containing monomer, an alkoxy group-containing monomer, a phosphoric acid group-containing monomer, a sulfonic acid group-containing monomer, a phenyl group-containing monomer, a silane group-containing monomer, a carboxylic acid group-containing monomer, and an amide group-containing (meth)acrylate.

The adhesive layer (400) may have a glass transition temperature of −10° C. or less, for example, −90° C. to −20° C. Within this range, the adhesive layer 400 can improve folding reliability of the optical member at low temperature.

The adhesive layer (400) may have a peel strength of 400 gf/inch or more, for example, 500 gf/inch to 1200 gf/inch, with respect to a PET film. Within this range, the adhesive layer (400) can maintain sufficient interfacial adhesion.

The adhesive layer (400) may further include particles to assist in improvement in flexibility of the surface protective film at low temperature and/or at high temperature or impact resistance of the surface protective film. The adhesive layer may include organic particles and/or inorganic particles.

The organic particles can improve reliability of the adhesive layer at high temperature by preventing delamination and/or lifting and/or bubble generation of the adhesive layer at high temperature through control of the modulus of the adhesive layer at high temperature. In particular, organic nanoparticles have a high glass transition temperature, thereby increasing the modulus of the adhesive layer at high temperature.

The organic particles may include organic nanoparticles having an average particle diameter of 10 nm to 400 nm, specifically 10 nm to 300 nm, more specifically 30 nm to 280 nm, more specifically 50 nm to 280 nm. Within this range, the organic particles can ensure that the adhesive layer has a total luminous transmittance of 90% or more in the visible spectrum and thus has good transparency, without affecting folding of the adhesive layer.

The organic particles may include core-shell type nanoparticles and simple nanoparticles, such as bead type nanoparticles, without being limited thereto. Preferably, the organic particles include core-shell type organic nanoparticles to further improve flexural reliability of the optical member according to the present invention at low temperature and at high temperature. A core and a shell of the organic nanoparticles may satisfy Equation 3. That is, both the core and the shell of the organic nanoparticles may be formed of an organic material. This particle morphology can lead to good foldability of the adhesive layer and good balance between elasticity and flexibility of the adhesive layer.

$$Tg ( c ) < Tg ( s ) \qquad [ Equation 3 ]$$

(in Equation 2, Tg(c) is a glass transition temperature of the core (unit: ° C.), and Tg(s) is a glass transition temperature of the shell (unit: ° C.).

The core may have a glass transition temperature of −150° C. to 10° C., specifically −150° C. to −5° C., more specifically −150° C. to −20° C. Within this range, the adhesive layer can have viscoelasticity at low temperature and/or at room temperature. The core may include at least one selected from among poly(alkyl (meth)acrylate), polysiloxane, or polybutadiene having a glass transition temperature in the above range. The poly(alkyl (meth)acrylate) may include at least one selected from among poly(methyl acrylate), poly(ethyl acrylate), poly(propyl acrylate), poly(butyl acrylate), poly(isopropyl acrylate), poly(hexyl acrylate), poly(hexyl methacrylate), poly(ethylhexyl methacrylate), and polysiloxane, without being limited thereto.

The shell may have a glass transition temperature of 15° C. to 150° C., specifically 35° C. to 150° C., more specifically 50° C. to 140° C. Within this range, the organic nanoparticles can have good dispersibility in the (meth)acrylic copolymer. The shell may include poly(alkyl methacrylate) having a glass transition temperature in the above range. For example, the shell may include at least one selected from among poly(methyl methacrylate) (PMMA), poly(ethyl methacrylate), poly(propyl methacrylate), poly(butyl methacrylate), poly(isopropyl methacrylate), poly(isobutyl methacrylate), and poly(cyclohexyl methacrylate), without being limited thereto.

The core may be present in an amount of 30 wt % to 99 wt %, specifically 40 wt % to 95 wt %, more specifically 50 wt % to 90 wt %, in the organic particles. Within this range, the adhesive layer can have good foldability over a wide temperature range. The shell may present in an amount of 1 wt % to 70 wt %, specifically 5 wt % to 60 wt %, more specifically 10 wt % to 50 wt %, in the organic particles. Within this range, the adhesive layer can have good foldability over a wide temperature range.

The organic particles may be present in an amount of 0 parts by weight to 20 parts by weight, specifically 0.1 parts by weight to 20 parts by weight, 0.5 parts by weight to 10 parts by weight, or 0.5 parts by weight to 8 parts by weight, relative to 100 parts by weight of the monomer mixture. Within this range, the adhesive layer can have high modulus at high temperature, good foldability at room temperature and at high temperature, and good viscoelasticity at low temperature and/or at room temperature.

The inorganic particles refer to particles formed of an inorganic material and may help to improve impact resistance of the surface protective film. The inorganic particles may include, for example, a metal oxide, such as silica and zirconia, a metal titanate, such as barium titanate, a sulfide, a selenide, a telluride, and the like. Preferably, the inorganic particles include silica to improve impact resistance of the adhesive layer and to prevent increase in haze of the adhesive film by reducing a difference in index of refraction between the inorganic particles and an adhesive resin constituting the adhesive layer.

The inorganic particles may include particles having a smaller average particle diameter than the organic particles. With this structure, the inorganic particles can more easily realize the effects of the present invention. The inorganic particles may include nanoparticles having an average particle diameter (D50) of 10 nm to 200 nm, specifically 10 nm to 150 nm, more specifically 10 nm to 100 nm. Within this range, the inorganic particles can improve impact resistance of the surface protective film without affecting folding of the surface protective film and can ensure that the adhesive layer has a total luminous transmittance of 90% or more and a haze of less than 1% in the visible spectrum and thus has good transparency. The average diameter D50 of the inorganic particles may be measured by a typical method known to those skilled in the art or may be obtained from product catalogs. For example, “average particle size (D50)” may mean the particle size of the inorganic particles corresponding to 50 volume % or 50 weight % when the inorganic particles are distributed from smallest to largest in terms of volume or weight.

The inorganic particles may be present in an amount of 0 parts by weight to 20 parts by weight, specifically 0.1 parts by weight to 20 parts by weight, 0.5 parts by weight to 10 parts by weight, or 0.5 parts by weight to 8 parts by weight, relative to 100 parts by weight of the monomer mixture including a hydroxyl group-containing (meth)acrylate and a comonomer. Within this range, the inorganic particles can significantly improve impact resistance of the surface protective film without affecting flexibility of the surface protective film.

The initiator is substantially the same as the initiator used in the hard coating layer composition described above.

The initiator may be present in an amount of 0.001 parts by weight to 10 parts by weight, specifically 0.001 parts by weight to 5 parts by weight, relative to 100 parts by weight of the monomer mixture including the hydroxyl group-containing (meth)acrylate and the comonomer. Within this range, the initiator can facilitate formation of the adhesive layer and can prevent reduction in transparency of the surface protective film.

The adhesive layer composition may further include a crosslinking agent and a silane coupling agent. The crosslinking agent may include a bi- to hexafunctional (meth)acrylate-based photocurable monomer. Details thereof are well known to those skilled in the art.

### [Optical Functional Layer]

The optical functional layer (300) is formed on the upper surface of the base layer (200) to provide additional functions to the optical member.

As shown in FIG. 1, each of upper and lower surfaces of the optical functional layer (300) is a generally flat surface

In one embodiment, the optical functional layer may provide one or more functions among hard coating, anti-glare, anti-fingerprint, antireflection, low-reflection, glare reduction, antifouling, diffusion, and refraction functions. Preferably, the optical functional layer is a hard coating layer to facilitate improvement in indentation resistance and impact resistance of the optical member when the optical member is disposed at a viewer side of an optical display device. In the following, the present invention will be described using an example in which the optical functional layer is a hard coating layer.

The hard coating layer may be formed of a (meth)acrylic, urethane, urethane (meth)acrylate, epoxy, or silicone-based coating layer composition. In one embodiment, the hard coating layer may be a urethane (meth)acrylate-based coating layer to improve impact resistance and indentation resistance of the optical member.

The hard coating layer may be formed of a urethane (meth)acrylate-based hard coating layer composition that includes a urethane (meth)acrylate oligomer, a (meth)acrylate monomer, inorganic particles, and an initiator.

The urethane (meth)acrylate oligomer may be prepared by polymerization of a polyfunctional polyol, a polyfunctional isocyanate compound, and a hydroxyl group-containing (meth)acrylate compound. The polyfunctional polyol may include any of the polyfunctional polyols described above, and the polyfunctional isocyanate compound may include any of the polyfunctional isocyanate compounds described above. The hydroxyl group-containing (meth)acrylate compound may include hydroxyethyl (meth)acrylate, pentaerythritol tri(meth)acrylate, dipentaerythritol penta(meth)acrylate, hydroxypropyl (meth)acrylate, hydroxybutyl (meth)acrylate, chlorohydroxypropyl (meth)acrylate, hydroxylhexyl (meth)acrylate, and the like, without being limited thereto.

The urethane (meth)acrylate oligomer may include only one type of urethane (meth)acrylate oligomer, or may include a mixture of two or more types of urethane (meth)acrylate oligomers having different elongations or weight average molecular weights. For example, the mixture may include a first urethane (meth)acrylate oligomer and a second urethane (meth)acrylate oligomer.

The first urethane (meth)acrylate oligomer may be hepta- to decafunctional (meth)acrylate oligomer and may have a weight average molecular weight of 1,000 g/mol to less than 4,000 g/mol and an elongation of 1% to less than 15%. Preferably, the first urethane (meth)acrylate oligomer is a nona- to decafunctional (meth)acrylate oligomer having a weight average molecular weight of 1,500 g/mol to 2,500 g/mol and an elongation of 5% to 10%. Within these ranges, the first urethane (meth)acrylate oligomer can help to improve impact resistance, scratch resistance, and flexibility of the optical member.

The second urethane (meth)acrylate oligomer may be tetra- to hexafunctional (meth)acrylate oligomer and may have a weight average molecular weight of 4,000 g/mol to 8,000 g/mol and an elongation of 15% to 25%. Preferably, the second urethane (meth)acrylate oligomer is a penta- to hexafunctional (meth)acrylate oligomer having a weight average molecular weight of 4,000 g/mol to 6,000 g/mol and an elongation of 15% to 20%. Within these ranges, the optical member can achieve improvement in impact resistance, scratch resistance, and foldability even with a thin hard coating layer while further ensuring stretchability of the hard coating layer.

The “elongation” of the urethane (meth)acrylate oligomer means a value measured on a specimen having a thickness of 200 μm and a width of 10 mm using an Instron device at a cuck distance of 30 mm (in accordance with JIS K7311).

In terms of solid content, the urethane (meth)acrylate oligomer may be present in an amount of 40 parts by weight to 80 parts by weight relative to a total of 100 parts by weight of the urethane (meth)acrylate oligomer, the (meth)acrylate monomer, and the inorganic particles. Within this range, the optical member can have good properties in terms of impact resistance, scratch resistance, and foldability. Herein, “solid content” refers to the content of all components of the hard coating layer composition excluding a solvent.

The (meth)acrylate monomer is a bi- to hexafunctional (meth)acrylate monomer and serves to improve hardness of the hard coating layer by being cured together with the first urethane (meth)acrylate oligomer and the second urethane (meth)acrylate oligomer.

The (meth)acrylate monomer may include: bifunctional (meth)acrylates, such as 1,4-butanediol di(meth)acrylate, 1,6-hexanediol di(meth)acrylate, neopentyl glycol di(meth)acrylate, polyethylene glycol di(meth)acrylate, neopentyl glycol adipate di(meth)acrylate, dicyclopentanyl di(meth)acrylate, caprolactone-modified dicyclopentenyl di(meth)acrylate, ethylene oxide-modified di(meth)acrylate, di(meth)acryloxyethyl isocyanurate, allylated cyclohexyl di(meth)acrylate, tricyclodecane dimethanol (meth)acrylate, dimethylol dicyclopentane di(meth)acrylate, ethylene oxide-modified hexahydrophthalic acid di(meth)acrylate, tricyclodecane dimethanol (meth)acrylate, neopentyl glycol-modified trimethylpropane di(meth)acrylate, adamantane di(meth)acrylate, or 9,9-bis[4-(2-acryloyloxyethoxy)phenyl]fluorene; trifunctional (meth)acrylates, such as trimethylolpropane tri(meth)acrylate, dipentaerythritol tri(meth)acrylate, propionic acid-modified dipentaerythritol tri(meth)acrylate, pentaerythritol tri(meth)acrylate, propylene oxide-modified trimethylolpropane tri(meth)acrylate, or tris(meth)acryloxyethyl isocyanurate; tetrafunctional (meth)acrylates, such as diglycerin tetra(meth)acrylate or pentaerythritol tetra(meth)acrylate; pentafunctional (meth)acrylates, such as dipentaerythritol penta(meth)acrylate; and hexafunctional (meth)acrylates, such as dipentaerythritol hexa(meth)acrylate or caprolactone-modified dipentaerythritol hexa(meth)acrylate, without being limited thereto. Preferably, the (meth)acrylate monomer is a tri- or tetrafunctional (meth)acrylate monomer to further improve impact resistance and scratch resistance of the optical member through adjustment of crosslinking density.

The (meth)acrylate monomer may be present in an amount of 1 part by weight to 30 parts by weight, for example, 5 parts by weight to 20 parts by weight or 5 parts by weight to 15 parts by weight, relative to a total of 100 parts by weight of the urethane (meth)acrylate oligomer, the (meth)acrylate monomer, and the inorganic particles. Within this range, the optical member can achieve improvement in impact resistance, scratch resistance, and foldability even with a thin hard coating layer.

In the hard coating layer, the inorganic particles serve to improve abrasion resistance and scratch resistance of a surface protective film. The inorganic particles may include at least one selected from among silica, alumina, and zirconia. The inorganic particles may have an average particle diameter (D50) of 200 nm or less, specifically greater than 0 nm to 200 nm, more specifically 5 nm to 100 nm. Within this range, the inorganic particles can improve scratch resistance of the surface protective film without increase in haze of the hard coating layer. The average diameter D50 of the inorganic particles may be measured by a typical method known to those skilled in the art or may be obtained from product catalogs. For example, the average particle size (D50) may mean the particle size of the inorganic particles corresponding to 50 volume % or 50 weight % in analysis of the inorganic particles in terms of volume or weight.

The inorganic particles may be present in an amount of 0.01 parts by weight to 10 parts by weight, for example, 1 part by weight to 4 parts by weight, relative to a total of 100 parts by weight of the urethane (meth)acrylate oligomer, the (meth)acrylate monomer, and the inorganic particles. Within this range, the optical member can achieve improvement in impact resistance, scratch resistance, and foldability even with a thin hard coating layer.

The initiator may include at least one selected from among a photoinitiator and a thermal initiator. Preferably, the initiator includes a photoinitiator to secure surface uniformity of the hard coating layer by preventing curing-induced shrinkage of the hard coating layer composition during curing of the hard coating layer composition.

The initiator may be an acetophenone compound, a benzyl ketal type compound, or a mixture thereof, without being limited thereto.

The initiator may be present in an amount of 0.01 parts by weight to 10 parts by weight, specifically 1 part by weight to 5 parts by weight, relative to a total of 100 parts by weight of the urethane (meth)acrylate oligomer, the (meth)acrylate monomer, and the inorganic particles. Within this range, the composition can achieve complete curing reaction without reduction in transmittance due to residues of the initiator and can reduce bubbling while securing good reactivity.

The hard coating layer composition may further include at least one selected from among a fluorine-based additive and a silicone-based additive.

The fluorine-based additive serves to improve abrasion resistance of the hard coating layer by improving surface properties of the hard coating layer, particularly slip properties of the hard coating layer, and may include any typical fluorine-based additive known to those skilled in the art. The fluorine-based additive may include at least one selected from among a fluorine-modified (meth)acrylate and a fluorine-modified siloxane compound.

The fluorine-based additive may be present in an amount of 0.01 parts by weight to 5 parts by weight, specifically 0.1 parts by weight to 2 parts by weight, relative to a total of 100 parts by weight of the urethane (meth)acrylate oligomer, the (meth)acrylate monomer, and the inorganic particles. Within this range, the fluorine-based additive can improve surface properties of the hard coating layer without affecting the other components of the composition.

The silicone-based additive serves to improve surface properties of the hard coating layer and may include any typical silicone-based additive known to those skilled in the art. For example, the silicone-based additive may include a polyether-modified acrylic polydimethylsiloxane, without being limited thereto.

The silicone-based additive may be present in an amount of 0.01 parts by weight to 5 parts by weight, specifically 0.1 parts by weight to 2 parts by weight or 0.1 parts by weight to 1 part by weight, relative to a total of 100 parts by weight of the urethane (meth)acrylate oligomer, the (meth)acrylate monomer, and the inorganic particles. Within this range, the silicone-based additive can improve surface properties of the hard coating layer without affecting the other components of the composition.

The hard coating layer may further include typical additives known to those skilled in the art to impart additional functionality to the hard coating layer. The additives may include an antioxidant, a stabilizer, a surfactant, a pigment, an antistatic agent, and a leveling agent, without being limited thereto.

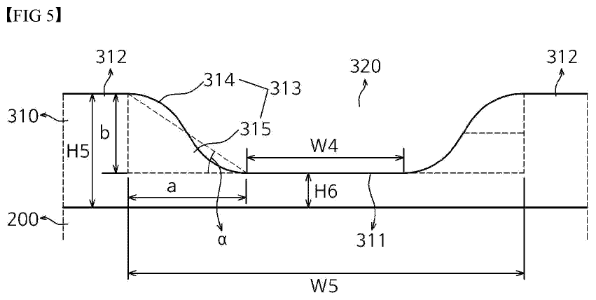

Next, an optical member according to another embodiment of the present invention will be described with reference to FIG. 5.

The optical member according to this embodiment includes a base layer; an impact resistance layer and an adhesive layer sequentially formed on a lower surface of the base layer; and an optical functional layer formed on an upper surface of the base layer, wherein the impact resistance layer includes a groove at a side of the adhesive layer and a flat portion at both sides of the groove, and the impact resistance layer satisfies Equation 1. Further, the optical member includes a groove formed on one surface thereof and a flat portion at both sides of the groove.

The optical member according to this embodiment is substantially the same as the optical member described with reference to FIG. 1 with respect to the base layer, the impact resistance layer, and the adhesive layer except for the groove on one surface of the optical functional layer and the flat portion at both sides of the groove. With respect to the optical functional layer, the optical member described in FIG. 1 has a flat upper surface and a flat lower surface, whereas the optical member described in FIG. 5 differs only in that the groove is formed on the base layer side of the optical functional layer and the flat portion is formed at both sides of the groove.

The optical functional layer (310) may include a groove (320) on an upper surface thereof opposite the base layer (200) and a flat portion (312) at both sides of the groove (320).

The flat portion (312) may have a height H5 of 10 μm to 1,000 μm, for example, 10, 20, 30, 40, 50, 60, 70, 80, 90, 100, 150, 200, 300, 400, 500, 600, 700, 800, 900, or 1,000 μm, preferably 10 μm to 500 μm, more preferably 30 μm to 100 μm. Within this range, the optical member can have improved resistance to impact and indentation.

The groove (320) includes a second surface (311) and an inclined surface (313) connected to the second surface (311). The inclined surface (313) is formed with a convex portion (314) extending from the flat portion (312) and a concave portion (315) connected to the convex portion (314). The convex portion (314) is convexly formed from the optical functional layer (310) side towards the groove (320). The concave portion (315) is convexly formed from the groove (320) side towards the optical functional layer (310).

Each of the convex portion (314) and the concave portion (315) is a curved surface and the inclined surface (313) may satisfy Equation 4:

$$a \geq b \qquad [ Equation 4 ]$$

(in Equation 4,
a is a width of the inclined surface formed with the convex portion, and
b is a height of the inclined surface formed with the convex portion).

In one embodiment, a may range from greater than 0 μm to 100,000 μm, for example, 1, 100, 500, 1,000, 1,500, 2,000, 2,500, 3,000, 3,500, 4,000, 4,500, 5,000, 5,500, 6,000, 6,500, 7,000, 7,500, 8,000, 8,500, 9,000, 9,500, 10,000, 10,500, 11,000, 11,500, 12,000, 12,500, 13,000, 13,500, 14,000, 14,500, 15,000, 15,500, 16,000, 16,500, 17,000, 17,500, 18,000, 18,500, 19,000, 19,500, 20,000, 21,000, 22,000, 23,000, 24,000, 25,000, 26,000, 27,000, 28,000, 29,000, 30,000, 31,000, 32,000, 33,000, 34,000, 35,000, 36,000, 37,000, 38,000, 39,000, 40,000, 41,000, 42,000, 43,000, 44,000, 45,000, 46,000, 47,000, 48,000, 49,000, 50,000, 51,000, 52,000, 53,000, 54,000, 55,000, 56,000, 57,000, 58,000, 59,000, 60,000, 70,000, 80,000, 90,000, or 100,000 μm, specifically 1 μm to 70,000 μm, and b may range from 1 μm to 300 μm, for example, 1, 5, 10, 20, 30, 40, 50, 60, 70, 80, 90, 100, 110, 120, 130, 140, 150, 160, 170, 180, 190, 200, 210, 220, 230, 240, 250, 260, 270, 280, 290, or 300 μm, specifically 10 μm to 200 μm. Within this range, the optical functional layer can easily realize the effects of the present invention and can facilitate manufacture of the impact resistance layer.

The convex portion (314) may have a radius of curvature of 1 mm or more. Within this range, the optical member can exhibit low repulsive force even upon repeated folding to be applied to a foldable display device and can improve the effect of minimizing visibility of the groove. Preferably, the convex portion (314) has a radius of curvature of 10 mm or more, more preferably 50 mm to 200 mm. Within this range, the optical functional layer can easily realize the effects of the present invention and can easily improve indentation resistance of the optical member.

The concave portion (315) may have a radius of curvature of 1 mm or more. Within this range, the optical member can exhibit low repulsive force even upon repeated folding to be applied to a foldable display device and can improve the effect of minimizing visibility of the groove. Preferably, the concave portion (315) has a radius of curvature of 10 mm or more, more preferably 50 mm to 200 mm. Within this range, the optical functional layer can easily realize the effects of the present invention and can easily improve indentation resistance of the optical member.

The radii of curvature of the convex portion (314) and the concave portion (315) may be measured substantially by the same method described with reference to FIG. 3.

The second surface (311) may have a height H6 of greater than 0 μm to 200 μm, for example, 1 μm to 50 μm. Within this range, the optical member can reduce repulsive force, thereby improving foldability.

The second surface (311) may have a maximum width W4 of 0 μm to 50,000 μm, for example, greater than 0 μm to 50,000 μm, for example, 1 μm to 30,000 μm. Within this range, the optical member can exhibit improved resistance to impact and indentation.

The groove (320) may have a maximum width W5 of 2 μm to 200,000 μm, specifically 50 μm to 100,000 μm. Within this range, the optical member can secure the folding effects.

An angle α of a plane (flat surface indicated by a dotted line) connecting the flat surface (112) to the second surface (311) with respect to a base of the inclined surface (313) may range from greater than 0° to 45°. Within this range, Equation 4 can be easily satisfied. Preferably, the angle α ranges from 0° to 10°.

### [Optical Display Device]

An optical display device according to the present invention includes the optical member according to the present invention. In one embodiment, the optical member may be disposed at a viewer side of the optical display device.

The optical display device may include: a light-emitting display device, such as an organic light-emitting display device and the like; a liquid crystal display device; and the like. The optical display device may be a foldable display device, without being limited thereto.

### MODE FOR INVENTION

Next, the present invention will be described in more detail with reference to some examples. However, it should be noted that these examples are provided for illustration only and are not to be construed in any way as limiting the present invention.

### Example 1

A hard coating layer composition (Shin-A T&C SEM100, urethane (meth)acrylate-based) was coated onto an upper surface of a PET film (thickness: 50 μm, TU-94, SKC Co., Ltd.) as a base layer and an impact resistance layer composition (solvent-free type, DS200EJ, Seconics Co., Ltd.) was pattern-coated onto a lower surface of the PET film, followed by attaching an adhesive layer (thickness: 50 μm, (meth)acrylate) to the PET film through a roll-to-roll process, thereby preparing an optical member as shown in FIGS. 1 and 2 and including an impact resistance layer as listed in Table 1.

### Examples 2 to 5

Optical members were prepared in the same manner as in Example 1 except that the parameters related to the impact resistance layer were changed as listed in Table 1.

### Comparative Example 1

An optical member was prepared in the same manner as in Example 1 except that the impact resistance layer was not formed with a groove and thus had a generally flat surface at the adhesive layer side.

Parameters related to each of the impact resistance layers of Examples 1 to 5 and Comparative Example are shown Table 1.

TABLE 1

| | H1 | H2 | H3 | L1 | R1 | R2 | W1 | W3 |
|---|---|---|---|---|---|---|---|---|
| | (μm) | (μm) | (μm) | (μm) | (mm) | (mm) | (μm) | (μm) |
| Example 1 | 10 | 60 | 50 | 5000 | 100 | 100 | 10,000 | 20,000 |
| Example 2 | 10 | 110 | 100 | 5000 | 100 | 100 | 10,000 | 20,000 |
| Example 3 | 10 | 60 | 50 | 10,000 | 100 | 100 | 10,000 | 20,000 |
| Example 4 | 10 | 110 | 100 | 1,000 | 100 | 100 | 10,000 | 20,000 |
| Example 5 | 10 | 60 | 50 | 20,000 | 100 | 100 | 10,000 | 20,000 |
| Comparative | — | 110 | — | — | — | — | — | — |
| Example 1 | | | | | | | | |

Each of the optical members prepared in Examples and Comparative Examples was evaluated as to the following properties. Results are shown in Table 2.

(1) Folding reliability: A specimen for evaluation of folding reliability was prepared by stacking an adhesive layer on a stack of PET film (thickness: 50 μm, TU-94, SKC Co., Ltd.)/adhesive layer/PET film (thickness: 50 μm, TU-94, SKC Co., Ltd.)/adhesive layer/PET film (thickness: 50 μm, TU-94, SKC Co., Ltd.), followed by attaching the optical member prepared in each of Examples and Comparative Examples to the adhesive layer. Here, a groove of the hard coating layer was disposed at the outermost side of the specimen. After the specimen was left at 25° C. for 72 hours, the specimen was manually folded and unfolded 20 times about the groove as the folding axis. Then, the presence of cracking and/or delamination on the groove was observed. When cracking and/or delamination was not observed, a corresponding specimen was rated as “o” and, when any cracking and/or delamination was observed, a corresponding specimen was rated as “X”.

(2) Visibility of groove: An adhesive layer was stacked on a foldable module, followed by attaching the optical member prepared in each of Examples and Comparative Examples to the adhesive layer. Then, the foldable module was operated, followed by observing visibility of the groove with the naked eye. When the groove was not visible, a corresponding specimen was rated as “o” and, when there was any visibility of the groove, a corresponding specimen was rated as “X”.

(3) Resistance to impact and indentation: The optical member prepared in each of Examples and Comparative Examples was placed on a glass plate with the hard coating layer disposed at the outermost side of the optical member. A pen having a dimeter of 0.7 mm and a circular cross-section was dropped vertically onto the groove of the hard coating layer. Then, the presence of an indentation and/or an imprint on the hard coating layer and the base layer was observed under a 3D microscope. A minimum height at which an indentation and/or an imprint was formed on the hard coating layer and the base layer upon dropping of the pen was measured. A greater height indicates better resistance to impact and indentation. When the height was 10 cm or higher, a corresponding specimen was rated as “o” and, when the height was less than 10 cm, a corresponding specimen was rated as

TABLE 2

| | |
|---|---|
| | Comparative |
| Example | Example |

| | 1 | 2 | 3 | 4 | 5 | 1 |
|---|---|---|---|---|---|---|
| Folding | ◯ | ◯ | ◯ | ◯ | ◯ | x |
| reliability | | | | | | |
| Visibility of | x | x | x | x | x | x |
| groove | | | | | | |
| Resistance to | ◯ | ◯ | ◯ | ◯ | ◯ | ◯ |
| impact and | | | | | | |
| indentation | | | | | | |

As shown in Table 2, it was confirmed that the optical members according to the present invention could be used in a foldable display device by securing low repulsive force even upon repeated folding, could be disposed at the outermost side of a display device by minimizing or eliminating visibility of the groove, and exhibited good impact or indentation resistance.

Conversely, the optical member of Comparative Example, not satisfying the requirements set forth herein, could not provide advantageous effects of the present invention.

It should be understood that various modifications, changes, alterations, and equivalent embodiments can be made by those skilled in the art without departing from the spirit and scope of the invention.

1. An optical member comprising:
a base layer; and an impact resistance layer and an adhesive layer sequentially formed on a lower surface of the base layer,
wherein the impact resistance layer comprises a groove at a side of the adhesive layer and a flat portion at both sides of the groove,
the impact resistance layer satisfying Equation 1:
$$0 \leq H 1 / H 2 < 1 \qquad [ Equation 1 ]$$
(in Equation 1,
H1 is a minimum height from the base layer side to the groove in the impact resistance layer (unit: μm), and
H2 is a height from the base layer side to the flat portion in the impact resistance layer (unit: μm)).

2. The optical member as claimed in claim 1, wherein H2 ranges from 10 μm to 1,000 μm and H1 ranges from 0 μm to 200 μm.

3. The optical member as claimed in claim 1, wherein the groove comprises a first surface corresponding to an uppermost surface and an inclined surface connecting the first surface to the flat portion.

4. The optical member as claimed in claim 3, wherein the inclined surface comprises a convex portion extending from the flat portion and a concave portion extending from the convex portion, and each of the convex portion and the concave portion is a curved surface.

5. The optical member as claimed in claim 4, wherein the inclined surface satisfies Equation 2:
$$L 1 \geq H 3 \qquad [ Equation 2 ]$$
(in Equation 2,
L1 is a width of the inclined surface formed with the convex portion (unit: μm), and
H3 is a height of the inclined surface formed with the convex portion (unit: μm)).

6. The optical member as claimed in claim 5, wherein L1 ranges from greater than 0 μm to 100,000 μm and H3 ranges from 1 μm to 300 μm.

7. The optical member as claimed in claim 5, wherein the convex portion has a radius of curvature of 1 mm or more and the concave portion has a radius of curvature of 1 mm or more.

8. The optical member as claimed in claim 1, wherein the adhesive layer has a storage modulus of 10 kPa to 500 kPa at 25° C.

9. The optical member as claimed in claim 1, wherein the adhesive layer has an index of refraction of 1.45 to 1.65.

10. The optical member as claimed in claim 1, further comprising:
an optical functional layer formed on an upper surface of the base layer.

11. The optical member as claimed in claim 10, wherein the optical functional layer is a hard coating layer.

12. The optical member as claimed in claim 11, wherein the hard coating layer is formed of a urethane (meth)acrylate based hard coating composition comprising a urethane (meth)acrylate based oligomer, a (meth)acrylate based monomer, inorganic particles, and an initiator.

13. The optical member as claimed in claim 10, wherein the optical functional layer comprises a groove formed on an upper surface thereof opposite the base layer and a flat portion at both sides of the groove.

14. The optical member as claimed in claim 13, wherein the groove comprises a second surface and an inclined surface connected to the second surface, and the inclined surface comprises a convex portion extending from the flat portion and a concave portion connected to the convex portion and the inclined surface satisfies Equation 4:
$$a \geq b \qquad [ Equation 4 ]$$
(in Equation 4,
a is a width of the inclined surface formed with the convex portion (unit: μm), and
b is a height of the inclined surface formed with the convex portion (unit: μm)).

15. An optical display device comprising the optical member as claimed in claim 1.
